(19) United States
(12) Patent Application Publication
(10) Pub. No.: US 2022/0293398 A1
(43) Pub. Date: Sep. 15, 2022

(54) SUBSTRATE PROCESSING APPARATUS

(71) Applicant: ASM IP Holding B.V., Almere (NL)

(72) Inventors: WonKi Jeong, Yongin-si (KR); HyungChul Moon, Cheonan-si (KR); GeunHwi Kim, Hwaseong-si (KR); JuIll Lee, Cheonan-si (KR); DaeYoun Kim, Seo-gu (KR)

(21) Appl. No.: 17/689,392

(22) Filed: Mar. 8, 2022

Related U.S. Application Data
(60) Provisional application No. 63/159,924, filed on Mar. 11, 2021.

(51) Int. Cl. H01J 37/32; H01L 21/263

(52) U.S. Cl. CPC H01J 37/32642; H01L 21/263; H01J 2237/332

(57) ABSTRACT

A substrate processing apparatus includes one or more reactors, which physically prevent a process gas in a reaction space from penetrating into a space other than the reaction space. Furthermore, provided is a substrate processing apparatus capable of minimizing the occurrence of parasitic plasma in a space other than a reaction space.

### CROSS-REFERENCE TO RELATED APPLICATIONS

This application claims the benefit of U.S. Provisional Application No. 63/159,924, filed on Mar. 11, 2021, in the United States Patent and Trademark Office, the disclosure of which is incorporated herein in its entirety by reference.

### BACKGROUND

### 1. Field

One or more embodiments relate to a substrate processing apparatus for suppressing parasitic plasma generation, and more particularly, to a substrate processing apparatus including a device for suppressing parasitic plasma generated in a lower space of a chamber apparatus.

### 2. Description of the Related Art

When processing a substrate in a reactor of a semiconductor and display processing apparatus, various gases are supplied to a reaction space. For example, a thin film is formed by periodically supplying source/reaction gases to a substrate. However, due to fluctuations in gas flow rate or fluctuations in process pressure resulting therefrom, some of the source/reaction gases may penetrate into a space (e.g., a lower space of a substrate support device) other than the reaction space through some gaps, and the thus penetrated gas may induce parasitic plasma during plasma processing.

When parasitic plasma is generated in a space other than the reaction space when RF power is supplied to the reaction space, plasma capacity that is supplied to a substrate in the reaction space and substantially contributes to the reaction is reduced by the amount of the generated parasitic plasma, which causes process failure.

### SUMMARY

One or more embodiments include a substrate processing apparatus including a device for suppressing parasitic plasma generated in a lower space of a chamber apparatus.

One or more embodiments include a physical device for minimizing the penetration of a process gas in a reaction space into a lower space of a chamber apparatus.

Additional aspects will be set forth in part in the description which follows and, in part, will be apparent from the description, or may be learned by practice of the presented embodiments of the disclosure.

According to one or more embodiments, a substrate processing apparatus includes one or more reactors, wherein each reactor includes: an upper body; a substrate support device; a control ring surrounding the substrate support device and seated on a step formed in the upper body, wherein there is a gap between the control ring and the substrate support device; and a blocking ring formed to surround the substrate support device at the bottom of the gap, wherein the upper body and the substrate support device form a reaction space, a lower area of the substrate support device forms a lower space, the reaction space and the lower space communicate through the gap, an inner diameter of the blocking ring is less than or equal to an outer diameter of the substrate support device, and an outer diameter of the blocking ring is greater than or equal to an inner diameter of the control ring.

According to an example of the substrate processing apparatus, an upper surface of the blocking ring may be in contact with a lower surface of the substrate support device and a lower surface of the control ring to prevent communication between the reaction space and the lower space through the gap.

According to an example of the substrate processing apparatus, a protrusion surrounding an outer circumferential surface of the blocking ring may be formed on the upper surface of the blocking ring, an inner diameter of the protrusion may be greater than or equal to the outer diameter of the substrate support device, a height of the protrusion may be equal to a vertical distance between the lower surface of the substrate support device and the lower surface of the control ring, the upper surface of the blocking ring and the protrusion may form a step having an upper surface, a lower surface, and a side surface connecting the upper surface to the lower surface, the upper surface of the step may contact the lower surface of the control ring, and the lower surface of the step may contact the lower surface of the substrate support device.

According to a further example of the substrate processing apparatus, the side surface of the step may have a structure inclined toward the lower surface of the step.

According to an example of the substrate processing apparatus, the inner diameter of the protrusion may be the same as the outer diameter of the substrate support device, and an interface between the side surface and the lower surface of the step may contact an interface between a side surface and the lower surface of the substrate support device.

According to a further example of the substrate processing apparatus, a width of the protrusion may be greater than or equal to the width of the gap.

According to a further example of the substrate processing apparatus, the blocking ring may include one or more extensions extending from an inner circumferential surface of the blocking ring toward the center of the blocking ring, and the extension may include a through hole through which a substrate support pin may pass.

According to a further example of the substrate processing apparatus, the substrate support device may include a pin hole through which the substrate support pin may pass, wherein a bushing having a hollow through which the substrate support pin may pass may be inserted into the pin hole of the substrate support device, and the length of the bushing may be greater than a thickness of the substrate support device.

According to a further example of the substrate processing apparatus, the bushing may pass through the through hole of the extension, a thread may be formed on a lower portion of the bushing, the thread may be fastened by a nut, and the extension may be located between the substrate support device and the thread.

According to a further example of the substrate processing apparatus, the extension may include at least one elastic body on an upper surface of the extension.

According to a further example of the substrate processing apparatus, the blocking ring may include one or more elastic bodies on at least one of the upper surface, the lower surface, and the side surface of the step.

According to a further example of the substrate processing apparatus, the substrate processing apparatus may further include: a blocking ring support arranged in the lower space; and a transfer arm configured to transfer the blocking ring.

According to a further example of the substrate processing apparatus, the transfer arm may be configured to raise the blocking ring so that the upper surface of the blocking ring contacts the lower surface of the substrate support device and the lower surface of the control ring at the start of the substrate processing process, and to lower the blocking ring to seat the blocking ring on the blocking ring support after completing the substrate processing process.

According to a further example of the substrate processing apparatus, the block ring support may include a step having an inclined structure.

According to one or more embodiments, a substrate processing apparatus includes one or more reactors, wherein each reactor includes: an upper body; a substrate support device; and a control ring apart from the substrate support device, surrounding the substrate support device, and seated on a step formed in the upper body, wherein a protrusion is formed under the substrate support device along an outer circumferential surface of the substrate support device, and the protrusion extends from a side surface of the substrate support device to a lower portion of the control ring.

According to a further example of the substrate processing apparatus, the protrusion may contact the lower surface of the control ring.

According to one or more embodiments, a substrate processing method using the above-described substrate processing apparatus, the substrate processing method includes: lowering the substrate support device; loading a substrate into the substrate support device; raising the substrate support device; raising the blocking ring so that an upper surface of the blocking ring contacts a lower surface of the substrate support device and a lower surface of the control ring; performing a substrate processing process; lowering the blocking ring; lowering the substrate support device; and unloading the substrate.

According to a further example of the substrate processing method, when the blocking ring does not contact the lower surfaces of the substrate support device and the control ring, the reaction space and the lower space may communicate with each other through the gap, and when the blocking ring contacts the lower surfaces of the substrate support device and the control ring, the reaction space and the lower space may not communicate with each other.

According to a further example of the substrate processing method, during the substrate processing process, gas introduced into the reaction space may not flow into the lower space by the blocking ring.

According to a further example of the substrate processing method, the substrate processing apparatus may include: a blocking ring support part arranged in the lower space; and a transfer arm configured to transfer the blocking ring, wherein the lowering of the blocking ring may include seating the blocking ring on the blocking ring support by the transfer arm.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view schematically illustrating a state in which a process gas in a reaction space penetrates into a lower space of a substrate support device in a reactor;

FIG. 2 is a schematic view of a substrate processing apparatus according to embodiments of the inventive concept;

FIG. 3 is a schematic view of a substrate processing apparatus equipped with a blocking ring according to embodiments of the inventive concept;

FIG. 4 is a schematic view of a blocking ring according to embodiments of the inventive concept;

FIG. 5 is a schematic view of a substrate processing apparatus equipped with the blocking ring of FIG. 4;

FIG. 6 is a schematic view of a blocking ring according to embodiments of the inventive concept;

FIG. 7 is a cross-sectional view of a substrate support device equipped with the blocking ring of FIG. 6;

FIG. 8 is a rear perspective view of a substrate support device on which the blocking ring and a substrate support pin of FIG. 6 are mounted;

FIG. 9 is a cross-sectional view of a substrate support device equipped with the blocking ring and the substrate support pin of FIG. 6;

FIG. 10 is a view of a substrate processing apparatus including two or more reactors according to embodiments of the inventive concept;

FIG. 11 is a schematic view of a substrate processing apparatus according to further embodiments of the inventive concept;

FIG. 12 is a schematic view of a blocking ring support and a blocking ring seated on the blocking ring support;

FIGS. 13A and 13B are schematic views of a blocking ring that is moved in a vertical direction by a transfer arm;

FIG. 14 is a perspective view of a chamber including two or more reactors according to embodiments of the inventive concept;

FIGS. 15A and 15B are views illustrating arrangement of a blocking ring and a transfer arm before and after a substrate process; and

FIG. 16 is a flowchart illustrating a substrate processing method according to embodiments of the inventive concept.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings.

In this regard, the present embodiments may have different forms and should not be construed as being limited to the descriptions set forth herein. Rather, these embodiments are provided so that the present disclosure will be thorough and complete, and will fully convey the scope of the present disclosure to one of ordinary skill in the art.

The terminology used herein is for describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected because of, for example, manufacturing techniques and/or tolerances. Thus, the embodiments of the disclosure should not be construed as being limited to the particular shapes of regions illustrated herein but may include deviations in shapes that result, for example, from manufacturing processes.

Although a deposition device of a semiconductor or a display substrate is described herein as the substrate processing apparatus, it is to be understood that the disclosure is not limited thereto. The substrate processing apparatus may be any device necessary for performing deposition of a material for forming a thin film, and may refer to a device in which a raw material for etching or polishing the material is uniformly supplied. Hereinafter, for convenience of description, it is assumed that the substrate processing apparatus is a semiconductor deposition device.

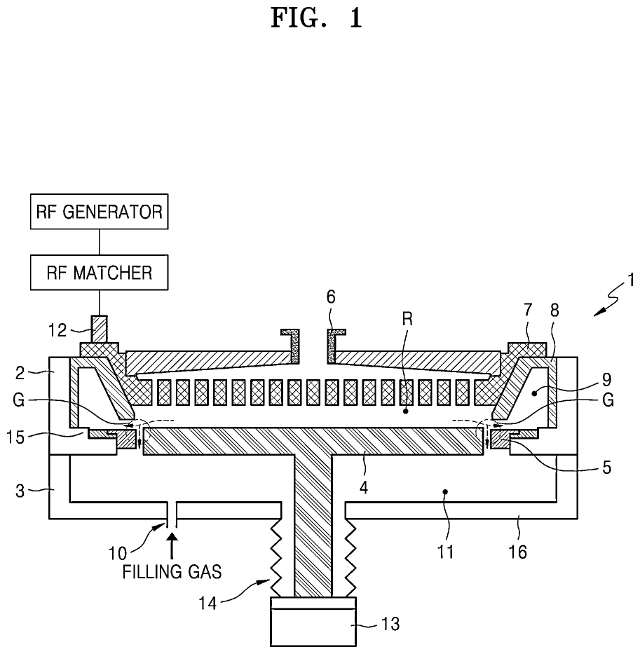

FIG. 1 is a view illustrating a state in which a process gas in a reaction space penetrates into a lower space of a substrate support device in a reactor of the substrate processing apparatus.

A reactor 1 in the substrate processing apparatus may include an upper body 2 and a lower body 3. The upper body 2 and the lower body 3 may be connected to each other. In more detail, the upper body 2 and the lower body 3 of the reactor 1 may form an inner space while face-contacting and face-sealing each other. The reactor 1 may include a substrate support device 4 and a control ring 5 in the inner space thereof.

The reactor may be a reactor in which an atomic layer deposition (ALD) or chemical vapor deposition (CVD) process is performed.

The upper body 2 of the reactor may include a source/reaction gas inlet 6, a gas supply unit 7, exhaust units 8 and 9, and the control ring 5. The lower body 3 of the reactor may include a filling gas inlet 10. The upper body 2 and the substrate support device 4 may form a reaction space R. A lower area of the substrate support device 4 may form a lower space 11. In more detail, the lower body 3 and the substrate support device 4 may form the lower space 11.

The gas supply unit 7 may be implemented in, for example, a lateral flow-type assembly structure or a showerhead-type assembly structure. The gas supply unit 7 is arranged to face the substrate support device 4 and may form the reaction space R together with the substrate support device 4.

A base of the gas supply unit 7 may include a plurality of gas supply unit holes formed (e.g., in a vertical direction) to eject a process gas. The gas supply unit 7 includes a metal material and may serve as an electrode during a plasma process. During the plasma process, a high frequency (RF) power source may be electrically connected to the gas supply unit 7 functioning as one electrode. In more detail, an RF rod 12 connected to the RF power source may pass through a reactor wall and be connected to the gas supply unit 7. Alternatively, the RF rod 12 may be a portion of the gas supply unit 7. In this case, the substrate support device 4 may function as the other electrode.

The substrate support device 4 may include a susceptor body for supporting a substrate and a heater for heating the substrate supported by the susceptor body. For loading/unloading of the substrate, the substrate support device 4 may be configured to be vertically movable by being connected to a driving unit 13 provided to one side of the substrate support device 4. The driving unit 13 may include a driving motor.

A stretchable portion 14 may be disposed between a lower surface of the lower body 3 and the driving unit 13. The stretchable portion 14 may be disposed between the lower surface of the lower body 3 and the driving unit 13 to isolate the lower space 11 from the outside.

The stretchable portion 14 may be stretched according to movement of the substrate support device 4. For example, the stretchable portion 14 may have a corrugated configuration (e.g., a bellows). In this case, when the substrate support device 4 and the driving unit 13 are raised, the stretchable portion 14 may contract, and when the substrate support device 4 and the driving unit 13 are lowered, the stretchable portion 14 may expand.

An exhaust unit may include an exhaust port (not shown), an exhaust duct 8, and an exhaust space 9 in the exhaust duct 8.

A step 15 facing the reaction space R may be formed in a lower portion of the upper body 2. The step 15 may have an upper surface, a lower surface, and a side surface connecting the upper surface to the lower surface. The exhaust duct 8 may be seated on an upper surface of the step 15. The gas supply unit 7 may be provided in an inner space surrounded by the exhaust duct 8.

The control ring 5 surrounds the substrate support device 4 and may be between the substrate support device 4 and the upper body 2. The control ring 5 may be seated on the step 15 formed in a lower portion of the upper body 2. In more detail, the control ring 5 may be seated on a lower surface of the step 15. Furthermore, the control ring 5 may be disposed below the exhaust duct 8. The control ring 5 may generally have a circular ring shape, but is not limited thereto. The control ring 5 may be fixed or movable with respect to the upper body 2.

Because the control ring 5 is apart from the substrate support device 4 and surrounds the substrate support device 4, there may be a gap G between the control ring 5 and the substrate support device 4. The reaction space R and the lower space 11 may communicate with each other through the gap G.

The control ring 5 may be a gas flow control ring (FCR). The control ring 5 may control a pressure balance between the reaction space R and the lower space 11 of the substrate support device 4 by adjusting a width of the gap G between the step 15 of the upper body 2 and the substrate support device 4, and may control an exhaust flow rate by adjusting a distance between the control ring 5 and a lower surface of the exhaust duct 8.

According to further embodiments, the control ring 5 may further include a stopper therebelow. The stopper may prevent excessive movement of the control ring 15 toward the reactor wall. The stopper may be disposed on a lower surface of the control ring 5.

Process gas introduced through a source/reaction gas inlet 6 may be supplied to the reaction space R and the substrate through the gas supply unit 7. A process gas supplied on the substrate may undergo a chemical reaction with the substrate or a chemical reaction between gases, and then deposit a thin film or etch a thin film on the substrate.

In addition, a filling gas may be introduced into the lower space 11 through the filling gas inlet 10. This filling gas forms a gas curtain in the gap G between the substrate support device 4 and the control ring 5 to prevent the gas in the reaction space R from flowing into the lower space 10 through the gap G. For example, the filling gas may be nitrogen or argon. Alternatively, a gas having a lower discharge rate than that of a gas supplied to the reaction space R may be supplied to the lower space 11 through the filling gas inlet 10 in order to prevent parasitic plasma from being generated in the lower space 11 when the plasma is generated in the reaction space R.

In a plasma process, upper RF power is supplied to the gas supply unit 7 through an RF generator, an RF matcher, and the RF rod 12, and a reaction gas introduced into the reaction space R through the source/reaction gas inlet 6 may be activated to generate plasma.

In the reaction space R, a residual gas or un-reacted gas remaining after the chemical reaction with the substrate may be exhausted to the outside through the exhaust space 9 in the exhaust duct 8 and an exhaust pump (not shown). An exhaust method may be upper exhaust or lower exhaust.

However, even though the filling gas introduced into the lower space 11 through the filling gas inlet 10 forms a gas curtain in the gap G, due to the fluctuation of a gas flow rate supplied during a substrate processing process or the fluctuation of a process pressure resulting therefrom, some of a source/reaction gas supplied to the reaction space R through the gas supply unit 7 may penetrate into the lower space 11 through the gap G (dashed arrows in FIG. 1). In addition, some of radicals in the reaction space R may flow into the lower space 11 through the gap G. The source/reaction gas and/or radicals penetrating into the lower space 11 in this way may induce parasitic plasma in the lower space 11 during a subsequent plasma process.

Also, when the gas supply unit 7 and a chamber bottom 16 face each other through the gap G, a potential difference may be formed, whereby a process gas and/or the filling gas introduced into the lower space 11 may be activated to form parasitic plasma in the lower space 11.

When parasitic plasma is generated in a space (i.e., the lower space 11) other than the reaction space R when RF power is supplied to the reaction space R, plasma capacity that is supplied to the substrate in the reaction space R and substantially contributes to the reaction is reduced by that amount of the generated parasitic plasma, which causes process failure.

Therefore, there is a need for a method of minimizing a problem that a gas in the reaction space R penetrates into the lower space 11 through the gap G and a problem of generating parasitic plasma in the lower space 11 by forming a potential difference as the gas supply unit 7 and the chamber bottom 16 face each other through the gap G.

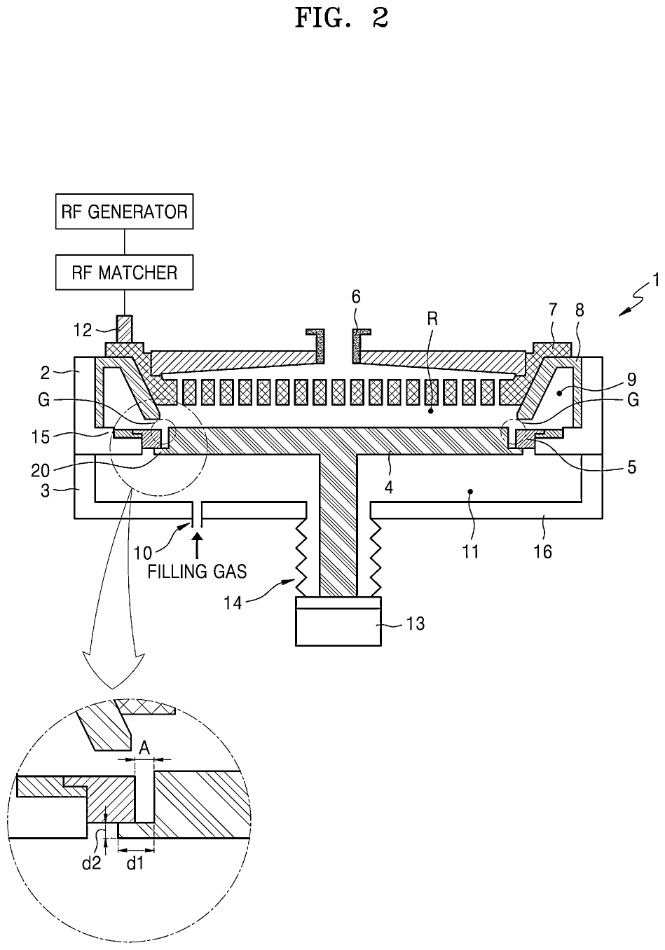

FIG. 2 is a view of a substrate processing apparatus according to embodiments of the inventive concept. In more detail, FIG. 2 schematically shows a substrate processing apparatus capable of preventing gas in the reaction space R from penetrating into the lower space 11 through the gap G. Hereinafter, repeated descriptions of the embodiments will not be given herein.

Unlike FIG. 1, a protrusion 20 formed along an outer circumferential surface of the substrate support device 4 is in a lower portion of the substrate support device 4 of FIG. 2. The protrusion 20 may extend from a side surface of the substrate support device 4 to a lower portion of the control ring 5. In more detail, the protrusion 20 may extend from the side surface of the substrate support device 4 to the lower portion of the control ring 5 across the gap G.

In contact with the control ring 5, a height of the protrusion 20 may be less than or equal to or greater than a vertical distance d2 between a lower surface of the substrate support device 4 and the lower surface of the control ring 5.

A radial width d1 of the protrusion 20 may be greater than or equal to a width A of the gap G. When the radial width d1 of the protrusion 20 is the same as the width A of the gap G, an interface between the upper and side surfaces of the protrusion 20 may contact an interface between the side and the lower surface of the control ring 5. Contacts between the protrusion 20 and the control ring 5 will form a circular contact line along the upper surface of the protrusion 20. Such a contact line may be a barrier that prevents a process gas in the reaction space R from penetrating into the lower space 11 through the gap G.

When the radial width d1 of the protrusion 20 is greater than the width A of the gap G, the protrusion 20 may contact the lower surface of the control ring 5. The contacts between the protrusion 20 and the control ring 5 will form an annular contact surface along the upper surface of the protrusion 20. Such a contact surface may be a barrier that prevents the process gas in the reaction space R from penetrating into the lower space 11 through the gap G.

As such, the protrusion 20 formed in a lower portion of the substrate support device 4 may be a barrier wall capable of physically preventing the process gas in the reaction space R from penetrating into the lower space 11 through the gap G. In addition, the protrusion 20 may be a barrier that physically blocks the formation of a potential difference when the gas supply unit 7 and the chamber bottom 16 face each other through the gap G. Accordingly, the protrusion 20 may prevent a problem that parasitic plasma is generated in the lower space 11.

According to the type of the substrate processing process, the elevation of the substrate support device 4 and a width of the reaction space R may vary. Accordingly, the protrusion 20 may be formed at any position on one surface, for example, at a side portion of the substrate support device 4 facing the control ring 5, in addition to the lower portion of the substrate support device 4. In this case, the radial width d1 of the protrusion 20 may be the same as the width A of the gap G, and a side surface of the protrusion 20 may contact a side surface of the control ring 5.

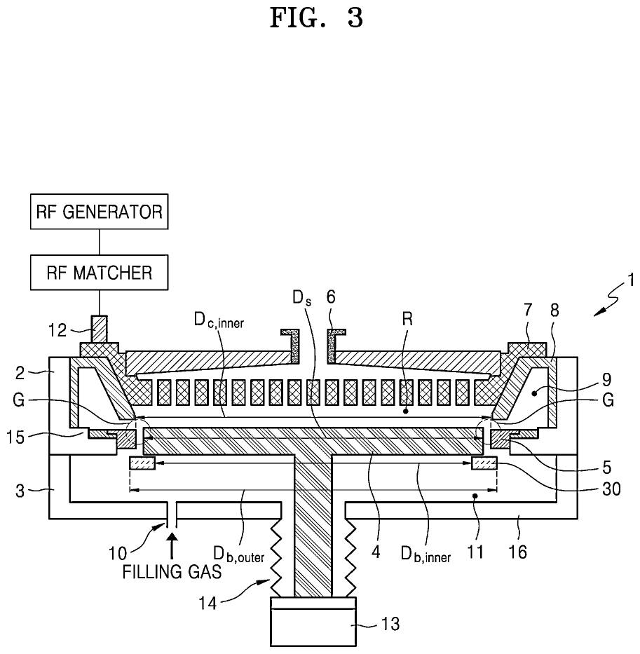

FIG. 3 is a view of a substrate processing apparatus equipped with a blocking ring according to embodiments of the inventive concept. In more detail, FIG. 3 schematically shows a substrate processing apparatus including a blocking ring 30 capable of preventing the gas supply unit 7 and the chamber bottom 16 from facing each other through the gap G. Hereinafter, repeated descriptions of the embodiments will not be given herein.

Unlike FIG. 1, the substrate processing apparatus of FIG. 3 further includes the blocking ring 30 formed to surround the substrate support device 4 below the gap G.

The blocking ring 30 may extend from the lower portion of the substrate support device 4 to the lower portion of the control ring 5. In order to prevent a potential difference from being formed by the gas supply unit 7 and the chamber bottom 16 facing each other through the gap G, an inner diameter (D_{b,inner}) of the blocking ring 30 may be less than or equal to an outer diameter (Dₛ) of the substrate support device 4, and an outer diameter (D_{b,outer}) of the blocking ring 30 may be greater than or equal to an inner diameter (D_{c,inner}) of the control ring 5.

The blocking ring 30 may generally have a circular ring shape, but is not limited thereto. The blocking ring 30 may be movable in the lower space 11.

An upper surface of the blocking ring 30 may or may not be in contact with the substrate support device 4 and/or the control ring 5.

When the blocking ring 30 does not contact the substrate support device 4 or the control ring 5, the reaction space R and the lower space 11 may communicate with each other through the gap G. In this case, the blocking ring 30 may not physically prevent the process gas in the reaction space R from penetrating into the lower space 11 through the gap G, but may serve as a barrier that physically blocks the formation of a potential difference when the gas supply unit 7 and the chamber bottom 16 face each other through the gap G. Accordingly, the blocking ring 30 may reduce a problem that parasitic plasma is formed in the lower space 11 by activating the process gas and/or the filling gas introduced into the lower space 11.

When the blocking ring 30 is in contact with the substrate support device 4 and the control ring 5, the blocking ring 30 may prevent the reaction space R and the lower space 11 from communicating with each other through the gap G. In more detail, when the upper surface of the blocking ring 30 is in contact with the lower surface of the substrate support device 4 and the lower surface of the control ring 5, a contact surface between the blocking ring 30 and the substrate support device 4 and the control ring 5 may serve as a barrier to prevent the process gas in the reaction space R from penetrating into the lower space 11 through the gap G. At the same time, the blocking ring 30 may serve as a barrier that physically blocks the formation of a potential difference when the gas supply unit 7 and the chamber bottom 16 face each other through the gap G. Accordingly, the blocking ring 30 may prevent a problem that parasitic plasma is generated in the lower space 11.

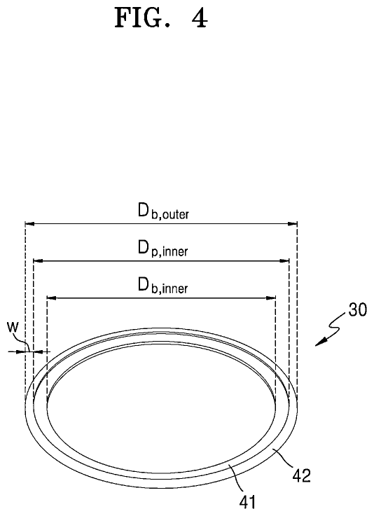

FIG. 4 is a schematic view of a blocking ring according to embodiments of the inventive concept. In more detail, FIG. 4 schematically shows an example of a blocking ring that may be used in the substrate processing apparatus of FIG. 3. Hereinafter, repeated descriptions of the embodiments will not be given herein.

The blocking ring 30 may include a body 41. The body 41 of the blocking ring 30 may generally have a circular ring shape, but is not limited thereto. As described above, in order to prevent the gas supply unit 7 and the chamber bottom 16 from facing each other through the gap G, an inner diameter (D_{b,inner}) of the blocking ring 30 may be less than or equal to an outer diameter of the substrate support device 4, and an outer diameter (D_{b,outer}) of the blocking ring 30 may be greater than or equal to the inner diameter of the control ring 5.

In a further embodiment, the upper surface of the blocking ring 30 (in more detail, an upper surface of the body 41) may be formed with a protrusion 42 surrounding an outer circumferential surface of the blocking ring 30. An inner diameter (D_{p,inner}) of the protrusion 42 may be greater than or equal to the outer diameter of the substrate support device 4.

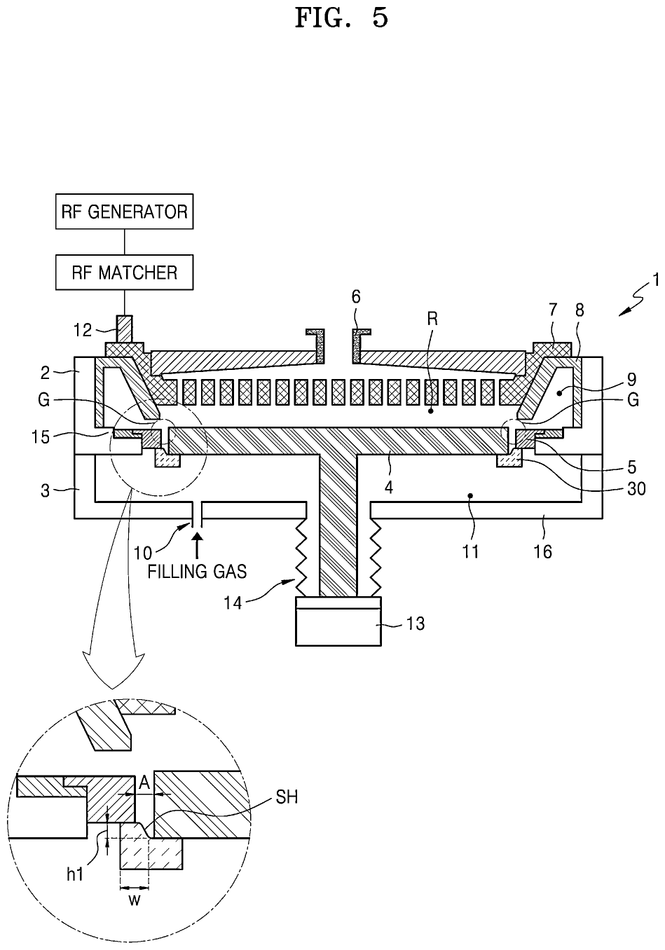

The upper surface of the blocking ring 30 and the protrusion 42 may form a step having an upper surface, a lower surface, and a side surface connecting the upper surface to the lower surface. As will be described later with reference to FIG. 5, the upper surface of the step (i.e., an upper surface of the protrusion 42) may contact the lower surface of the control ring 5, and the lower surface of the step (i.e., the upper surface of the body 41) may contact the lower surface of the substrate support device 4.

As will be described later with reference to FIG. 5, a width w of the protrusion 42 may be greater than or equal to a width of the gap, and a height of the protrusion 42 may be equal to a vertical distance between the lower surface of the substrate support device 4 and the lower surface of the control ring 5.

FIG. 5 is a view of a substrate processing apparatus equipped with the blocking ring of FIG. 4. In more detail, FIG. 5 shows a state in which the blocking ring 30 of FIG. 4 is in contact with the lower surface of the substrate support device 4 and the lower surface of the control ring 5.

As described above, the inner diameter (D_{b,inner}) of the blocking ring 30 may be configured to be less than or equal to the outer diameter of the substrate support device 4, and the inner diameter (D_{p,inner}) of the protrusion portion 42 may be configured to be greater than or equal to the outer diameter of the substrate support device 4. Therefore, a periphery of the lower surface of the substrate support device 4 may contact a lower surface of a step of the blocking ring 30.

When the inner diameter (D_{p,inner}) of the protrusion 42 is the same as the outer diameter of the substrate support device 4, an interface between a side surface and the lower surface of the step of the blocking ring 30 may contact an interface between the side surface and the lower surface of the substrate support device 4. That is, the interface between the side surface and the lower surface of the substrate support device 4 is in close contact with the step of the blocking ring 30, thereby fixing the position of the blocking ring 30.

The width w of the protrusion 42 may be configured to be greater than or equal to the width A of the gap, and a height h1 of the protrusion 42 may be configured to be equal to the vertical distance between the lower surface of the substrate support device 4 and the lower surface of the control ring 5. Therefore, a periphery of the lower surface of the control ring 5 may contact an upper surface of the step of the blocking ring 30 (i.e., the protrusion 42), and may block the process gas in the reaction space R from penetrating into the lower space 11 through the gap G.

A side surface of the step of the blocking ring 30 may have a structure SH that is inclined toward the lower surface of the step. This inclined structure may provide a self-aligning function that enables the blocking ring 30 to be accurately positioned in place when the blocking ring 30 is raised and in contact with the lower surface of the substrate support device 4. In a further embodiment, corresponding to the inclined structure SH of the step of the blocking ring 30, a lower edge portion of the substrate support device 4 may have a chamfered or inclined structure or a non-right angle structure having a radius of curvature. Therefore, the self-aligning function of the blocking ring 30 with respect to the substrate support device 4 may be further enhanced.

When the blocking ring 30 is in contact with the substrate support device 4 and the control ring 5 as shown in FIG. 5, the blocking ring 30 may prevent the reaction space R and the lower space 11 from communicating with each other through the gap G. In more detail, when the lower surface of the step of the blocking ring 30 is in contact with the lower surface of the substrate support device 4 and the upper surface of the step of the blocking ring 30 is in contact with the lower surface of the control ring 5, the contact surface between the blocking ring 30 and the substrate support device 4 and the control ring 5 may serve as a barrier to prevent the process gas in the reaction space R from penetrating into the lower space 11 through the gap G. At the same time, the blocking ring 30 may serve as a barrier that physically blocks the formation of a potential difference when the gas supply unit 7 and the chamber bottom 16 face each other through the gap G. Accordingly, the blocking ring 30 may prevent a problem that parasitic plasma is generated in the lower space 11.

That is, when the blocking ring 30 is configured by using the outer diameter of the substrate support device 4, the inner diameter of the control ring 5, and the vertical distance between the lower surface of the substrate support device 4 and the lower surface of the control ring 5, a problem that parasitic plasma is generated in the lower space 11 may be prevented.

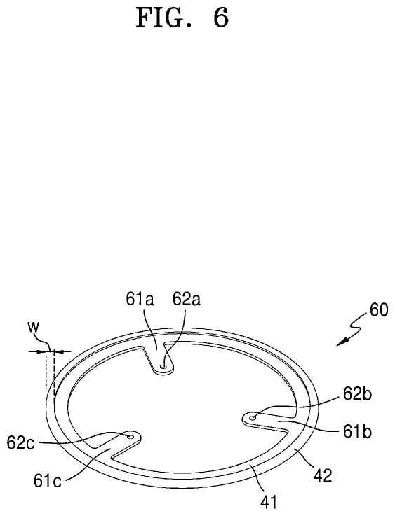

FIG. 6 is a schematic view of a blocking ring according to embodiments of the inventive concept. Hereinafter, repeated descriptions of the embodiments will not be given herein.

A blocking ring 60 of FIG. 6 may further include one or more extensions in addition to the configuration of the blocking ring 30 of FIG. 4. The blocking ring 60 of FIG. 6 is shown to include three extensions (a first extension 61a, a second extension 61b, and a third extension 61c), but is not limited thereto, and may include any number of extensions.

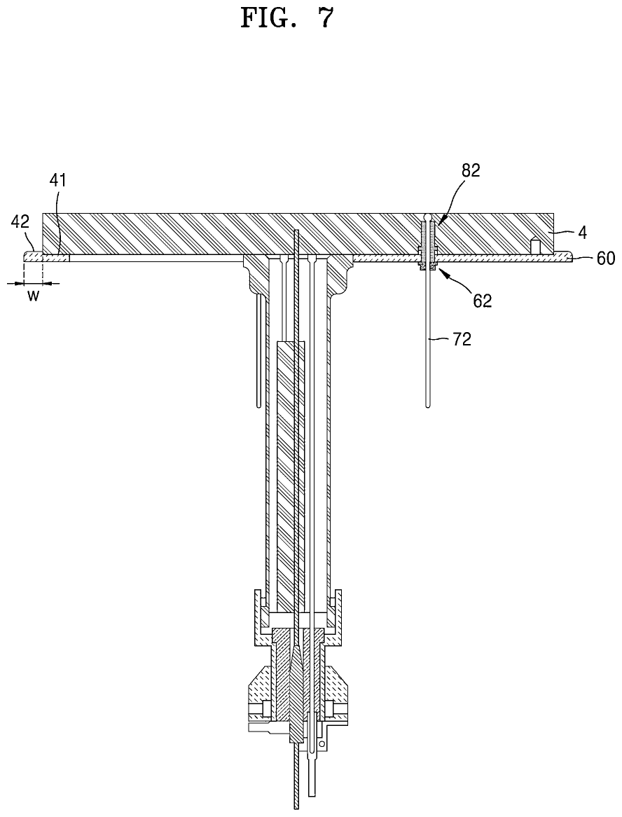

The first, second, and third extensions 61a, 61b, and 61c may extend from an inner circumferential surface of the blocking ring 60 toward the center of the blocking ring 60. Lengths of the extensions 61a, 61b and 61c may be less than a radius of the blocking ring 60. These first, second, and third extensions 61a, 61b, and 61c may maintain the position and alignment of the blocking ring 60 with respect to the lower surface of the substrate support device 4 as described with reference to FIGS. 7 to 9.

The first, second, and third extensions 61a, 61b, and 61c may include through holes 62a, 62b, and 62c through which the substrate support pin may pass, respectively. For smooth vertical movement of the substrate support pin, inner diameters of the through holes 62a, 62b, and 62c may be greater than a diameter of the substrate support pin.

FIG. 7 is a cross-sectional view of a substrate support device equipped with the blocking ring of FIG. 6. Hereinafter, repeated descriptions of the embodiments will not be given herein.

Referring to FIG. 7, the substrate support device 4 may include one or more pin holes 82 through which a substrate support pin 72 may pass. The substrate support pin 72 may pass through one of the pin holes 82 of the substrate support device 4 and one of the through holes 62a, 62b, and 62c of the blocking ring 60 corresponding thereto. The position and alignment of the blocking ring 60 with respect to the lower surface of the substrate support device 4 may be maintained by the substrate support pin 72.

As shown in FIG. 7, when an outer diameter of the blocking ring 60 is greater than the outer diameter of the substrate support device 4 and an inner diameter of the protrusion 42 is the same as the outer diameter of the substrate support device 4, an interface between a side surface and a lower surface of the step (protrusion) of the blocking ring 60 may contact the interface between the side surface and the lower surface of the substrate support device 4. That is, the interface between the side surface and the lower surface of the substrate support device 4 may be in close contact with a step of the blocking ring 60, and due to the protrusion 42, the position of the blocking ring 60 may be fixed.

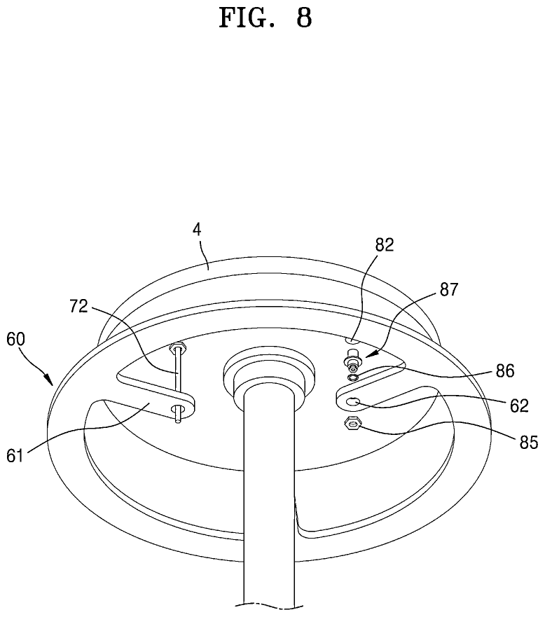

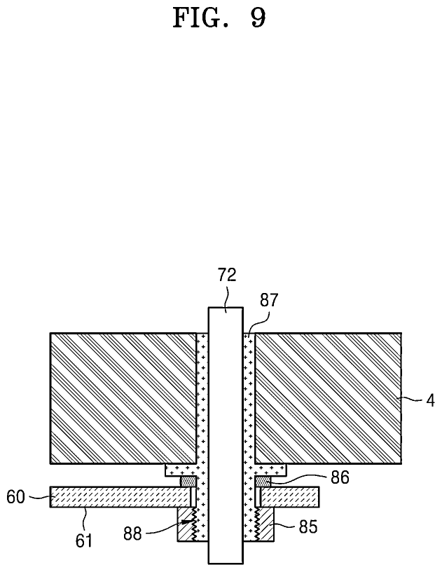

FIGS. 8 and 9 schematically show a rear perspective view and a cross-sectional view of a substrate support device to which the blocking ring and the substrate support pin of FIG. 6 are mounted, respectively. Hereinafter, repeated descriptions of the embodiments will not be given herein.

As shown in FIGS. 8 and 9, a bushing 87 having a hollow through which the substrate support pin 72 may pass may be inserted into the pin hole 82 of the substrate support device 4. A length of the bushing 87 is greater than a thickness of the substrate support device 4, so that the bushing 87 may extend further down than the substrate support device 4 through the substrate support device 4. The bushing 87 may pass through the pin hole 82 of the substrate support device 4 and pass through a through hole 62 of an extension 61 of the blocking ring 60.

The substrate support pin 72 may be inserted into a hollow area of the bushing 87 and may be moved vertically in the hollow by a substrate support pin driver (not shown) for loading/unloading a substrate. For smooth vertical movement of the substrate support pin 72, an inner diameter of the bushing 87 may be greater than a diameter of the substrate support pin 72.

In a further embodiment, an outer surface of a lower portion of the bushing 87 may be formed with a thread 88 that may be fastened by a nut 85. The extension 61 of the blocking ring 60 may be disposed between the substrate support device 4 and the thread 88, and the position may be fixed by fastening the thread 88 and the nut 85.

In a further embodiment, the extension 61 may include at least one elastic body 86 on an upper surface of the extension 61. The elastic body 86 may be disposed between the substrate support device 4 and the extension 61 of the blocking ring 60. The elastic body 86 may be, for example, a spring, a leaf spring, and a fluid or a gas, and may be implemented by a combination thereof. In another embodiment, the elastic body 86 may be or further disposed on the lower surface of the extension 60, e.g. between the extension 61 of the blocking ring 60 and the nut 85.

In FIGS. 8 and 9, the blocking ring 60 is fixed to the lower surface of the substrate support device 4 by the bushing 87 and the nut 85, and when the substrate support device 4 is raised to contact the blocking ring 60 and the control ring 5 (of FIG. 5), the elastic body 86 may alleviate an impact applied to the blocking ring 60, the substrate support device 4, and the control ring 5. In addition, it is possible to minimize damage to a device that may occur due to an impact applied to the blocking ring 60, the control ring 5, and the substrate support device 4, or the generation of contaminants such as particles which may occur due to the damage. By appropriately selecting the position of the elastic body 86, the impact to the parts may be more effectively controlled. For example, the elastic body 86 may be on at least one of an upper surface (i.e., a protrusion), a lower surface (i.e., a body), and a side surface of the step of the blocking ring 60 as well as the upper surface of the extension 61 or lower surface of the extension 61. In addition, the elastic body 86 may increase the degree of adhesion between the blocking ring 60, the substrate support device 4, the bushing 87 (in particular, the thread 88), and the nut 85.

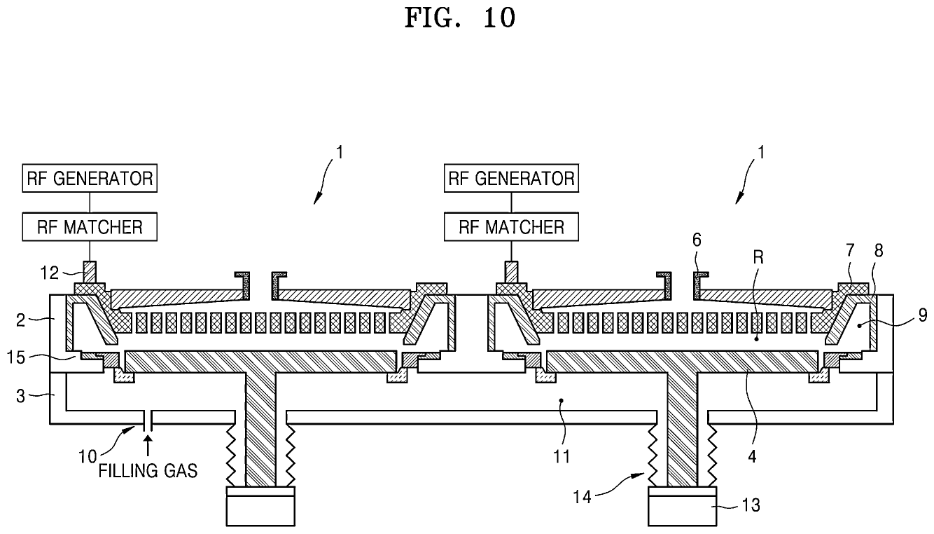

FIG. 10 is a view of a substrate processing apparatus including two or more reactors according to embodiments of the inventive concept. Hereinafter, repeated descriptions of the embodiments will not be given herein.

Although FIGS. 1 to 3 and 5 illustrate a substrate processing apparatus including one reactor 1, the object of the disclosure is not limited to one reactor that processes one substrate. In some examples, the disclosure may be used in a batch reactor (i.e., a plurality of reactors) that processes a plurality of substrates, that is, a batch of substrates at a time, as shown in FIG. 10. In the case of a chamber including a plurality of reactors, reactors 1 in the chamber may share the lower space 11 of the substrate support device 4.

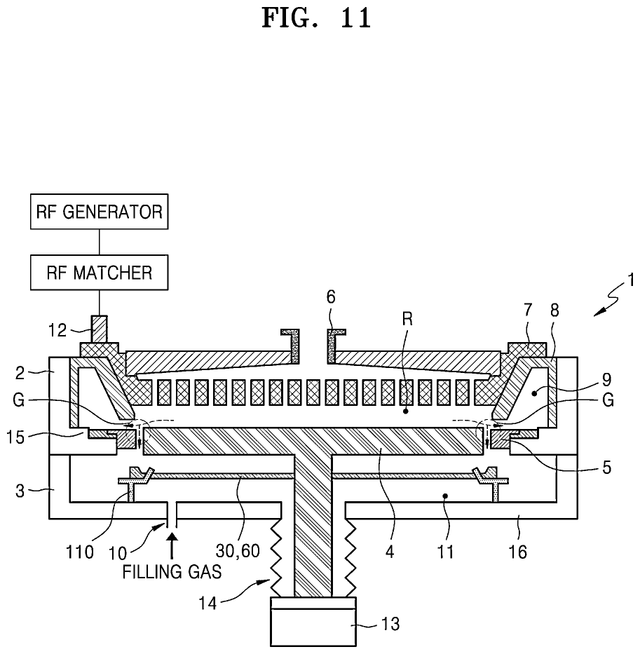

FIG. 11 is a schematic view of a substrate processing apparatus according to further embodiments of the inventive concept. In more detail, FIG. 11 schematically shows a substrate processing apparatus in which a blocking ring support 110 is arranged. In order to facilitate understanding of the drawings, it may be noted that the blocking rings 30 and 60 in FIG. 11 are represented by straight lines instead of the original cross-sectional shape.

Unlike the configuration of the reactors of FIGS. 1, 2, 3, and 5, in FIG. 11, the blocking ring support 110 may be arranged in the lower space 11. In more detail, the blocking ring support 110 may be installed on the chamber bottom 16. The blocking rings 30 and 60 may be seated on the blocking ring support 110.

The blocking rings 30 and 60 may be raised near the lower surface of the substrate support device 4 by a transfer arm (not shown) at the start of a substrate processing process, and may be seated on the blocking ring support 110 again by the transfer arm after the substrate processing process is completed.

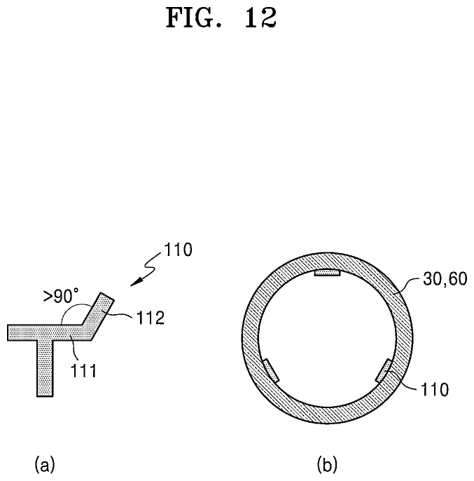

FIG. 12 (a) shows an example of the blocking ring support 110 that may be used in the substrate processing apparatus of FIG. 11, and FIG. 12 (b) schematically shows a top view of the blocking rings 30 and 60 seated on the blocking ring support 110. Hereinafter, repeated descriptions of the embodiments will not be given herein.

As shown in FIG. 12, an upper portion of the blocking ring support 110 may include a seating portion 111 on which the blocking rings 30 and 60 may be seated. A radial length of the seating portion 111 may be greater than or equal to a radial length of the blocking rings 30 and 60. A distance from the virtual center between a plurality of the seating portions 111 to the intersection between the seating portion 111 and the guide portion 112 of the blocking ring support 110 may be smaller than or equal to an inner diameter of the blocking rings 30 and 60.

The blocking ring support 110 may further include a guide portion 112 for maintaining the position of the blocking rings 30 and 60.

The seating portion 111 and the guide portion 112 may form a step. An interface between a side surface and a lower surface of the blocking rings 30 and 60 may be in close contact with the step of the blocking ring support 110 (in particular, an interface between the seating portion 111 and the guide portion 112), and the blocking rings 30 and 60 may be aligned or fixed to the blocking ring support 110.

As shown in FIG. 12 (a), the guide portion 112 may have a shape inclined at an angle of 90 degrees or more with respect to the seating portion 111. That is, the blocking ring support 110 may have a step having an inclined structure. This configuration may provide a self-aligning function that enables the blocking rings 30 and 60 to be accurately positioned in place when the blocking rings 30 and 60 are lowered and seated on the blocking ring support 110.

In FIG. 12 (b), the blocking ring support 110 is shown as having a three seating-guide portions set, but the disclosure is not limited thereto. For example, the blocking ring support 110 may have four seating portions.

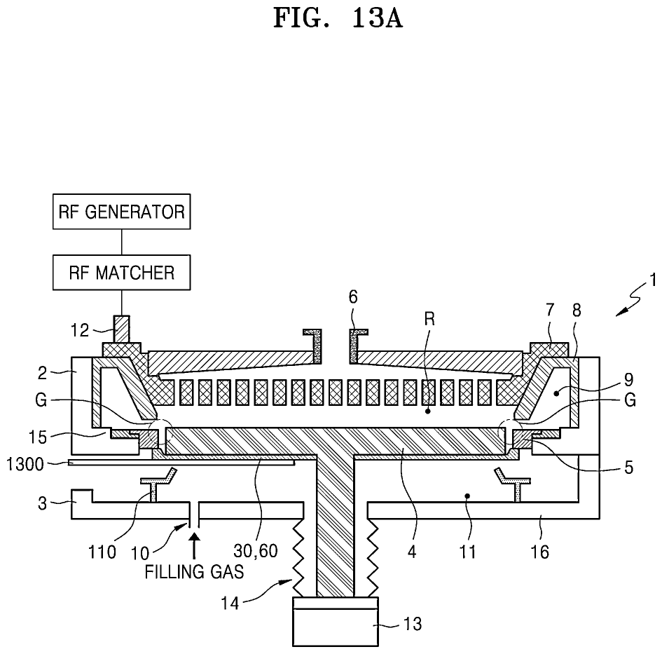

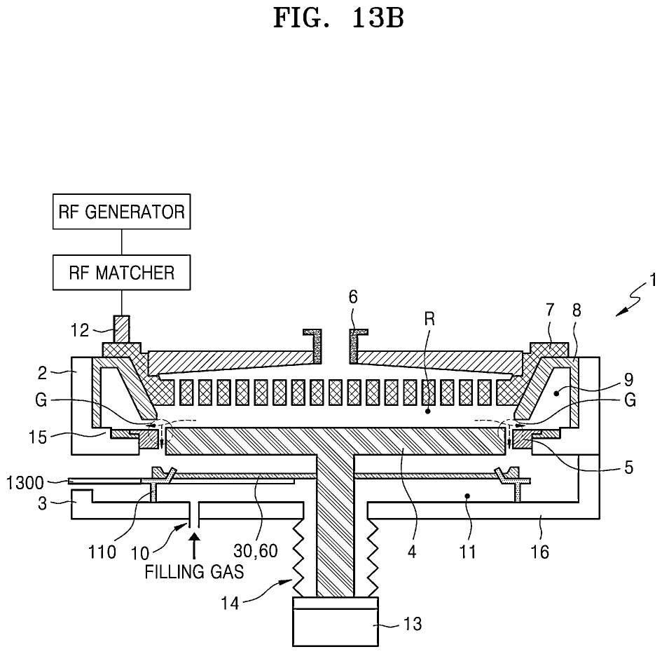

FIGS. 13A and 13B schematically show blocking rings 30 and 60 that are moved in a vertical direction by a transfer arm 1300. Although the blocking rings 30 and 60 generally have a ring structure, in order to facilitate understanding of the drawings, it may be noted that the blocking rings 30 and 60 in FIGS. 13A and 13B are represented by straight lines instead of the original cross-sectional shape. Hereinafter, repeated descriptions of the embodiments will not be given herein.

As shown in FIGS. 13A and 13B, the substrate processing apparatus may further include a transfer arm 1300 for transferring the blocking rings 30 and 60.

The transfer arm 1300 may be connected to a moving mechanism such as a rotating shaft (not shown) to be rotatable. In further embodiment, the transfer arm 1300 may be further connected to an elevating shaft to be movable upward/downward. The rotating shaft may be rotatable by a rotating motor (not shown), and may be lifted by a lifting motor (not shown), thereby enabling rotating/elevating movement of the transfer arm 1300.

The transfer arm 1300 is configured to raise the blocking rings 30 and 60 so that an upper surface of the blocking rings 30 and 60 are in contact with the lower surfaces of the substrate support device 4 and the control ring 5 at the start of a substrate processing process (see FIG. 13A). While the blocking rings 30 and 60 are rising, the blocking rings 30 and 60 may be supported by the transfer arm 1300. When the upper surfaces of the blocking rings 30 and 60 are in contact with the lower surfaces of the substrate support device 4 and the control ring 5, the reaction space R and the lower space 11 may not communicate with each other through the gap G.

The transfer arm 1300 may be configured to lower the blocking rings 30 and 60 to seat the blocking rings 30 and 60 on the blocking ring support 110 after completing the substrate processing process (see FIG. 13B). While the blocking rings 30 and 60 are lowering, the blocking rings 30 and 60 may be supported by the transfer arm 1300. While the blocking rings 30 and 60 are lowering, that is, when the blocking rings 30 and 60 are no longer in contact with the lower surfaces of the substrate support device 4 and the control ring 5, the reaction space R and the lower space 11 may communicate with each other through the gap G.

From FIGS. 13A and 13B, it can be seen that the blocking rings 30 and 60 may be movable in a vertical direction independently of the substrate support device 4 and may be movable using the transfer arm 1300 without a separate additional device.

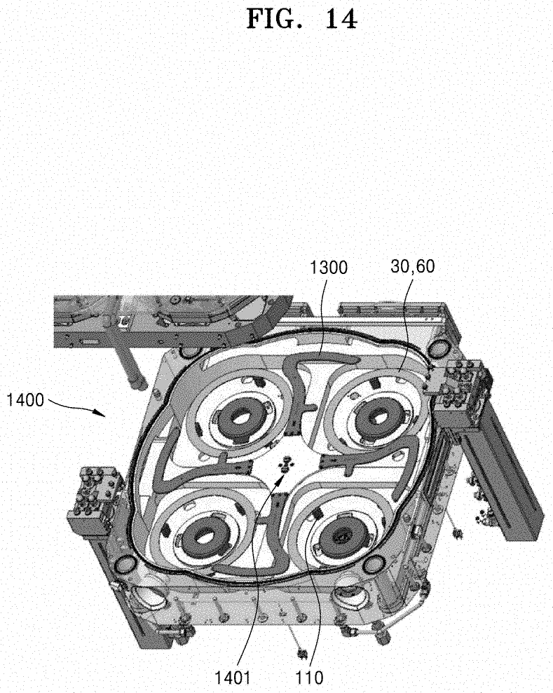

FIG. 14 is a perspective view of a chamber 1400 including two or more reactors according to embodiments of the inventive concept. In more detail, FIG. 14 shows a perspective view of the chamber 1400 including four reactors of FIG. 11 and/or FIG. 13. In FIG. 14, in order to facilitate understanding of the drawings, the illustration of a substrate support device is omitted. Hereinafter, repeated descriptions of the embodiments will not be given herein.

As shown in FIG. 14, the blocking ring support 110 is disposed in a lower space of each reactor, and the blocking rings 30 and 60 are seated on each blocking ring support 110. A rotating shaft 1401 may be between the blocking rings 30 and 60, may be rotated by a rotating motor (not shown), and may be lifted and lowered by a lifting motor (not shown). The transfer arm 1300 may be connected to the rotating shaft 1401 to enable rotating/elevating movement.

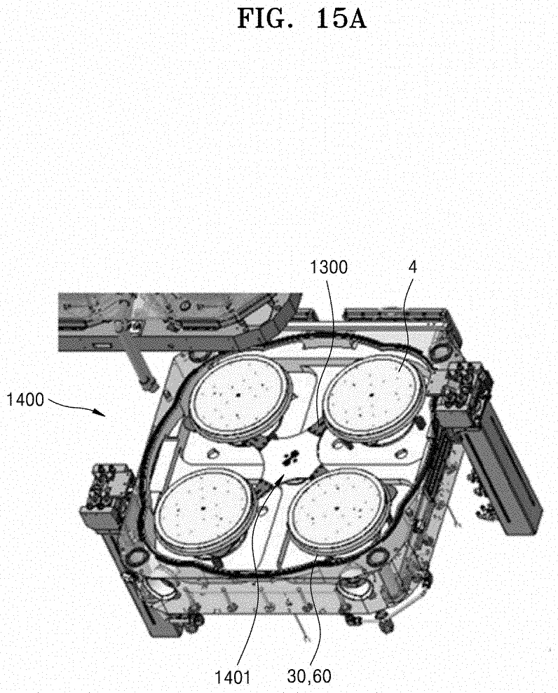

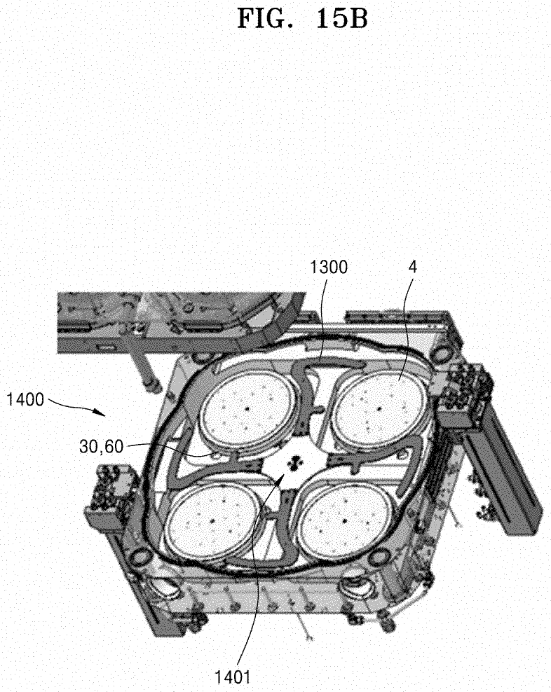

FIGS. 15A and 15B show the arrangement of a blocking ring and a transfer arm before and after substrate processing in a chamber of FIG. 14. In FIG. 15, in order to facilitate understanding of the drawings, the illustration of a gas supply unit, an upper body of a reactor, and a top lid of the chamber are omitted. However, unlike FIG. 14, the substrate support device 4 is shown in FIG. 15. Hereinafter, repeated descriptions of the embodiments will not be given herein.

During a substrate processing process, as shown in FIG. 15A, the blocking rings 30 and 60 are supported by the transfer arm 1300 and are moved upward to a lower surface of the substrate support device 4. In this case, as shown in FIG. 13A, the blocking rings 30 and 60 may physically separate a gap between the substrate support device 4 and a control ring 5 and a lower space. Accordingly, during the substrate processing process, a gas flowing into a reaction space may not be introduced into the lower space 11 by the blocking rings 30 and 60.

FIG. 15B shows a chamber in a state before processing a substrate for loading a substrate or after processing a substrate for unloading the substrate, or in an idle state. The blocking rings 30 and 60 are moved downward by the transfer arm 1300 to be seated on a blocking ring support, and the transfer arm 1300 may be disposed in a space between reactors, that is, a space between the blocking rings 30 and 60. As shown in FIG. 15B, the substrate support device 4 may also be lowered for substrate loading/unloading.

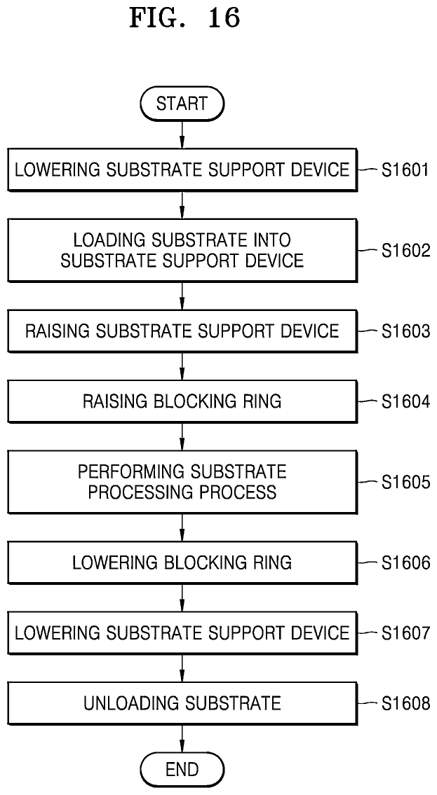

FIG. 16 is a flowchart illustrating a substrate processing method using a substrate processing apparatus according to embodiments of the inventive concept. Hereinafter, repeated descriptions of the embodiments will not be given herein.

First, operation S1601 of lowering a substrate support device (e.g., 4 in FIG. 13) may be performed. The substrate support device may be configured to be vertically movable by being connected to a driving unit (e.g., 13 in FIG. 13) provided to one side of the substrate support device.

Thereafter, operation S1602 of loading a substrate into the substrate support device by a substrate transfer mechanism may be performed. The substrate transfer mechanism may be the same as the transfer arm 1300 or may be a separate device.

Thereafter, operation S1603 of raising the substrate support device may be performed. The substrate support device may be raised by a driving unit (e.g., a driving motor).

Thereafter, operation S1604 of raising a blocking ring (e.g., 30 and 60 in FIG. 13) may be performed. The blocking ring may be supported by a transfer arm (e.g., 1300 in FIG. 13) and may be raised. To physically separate a gap between the substrate support device and the control ring and the lower space, the transfer arm may raise the blocking ring to a lower surface of the substrate support device so that an upper surface of the blocking ring contacts the lower surface of the substrate support device and a lower surface of the control ring.

Thereafter, operation S1605 of performing a substrate processing process may be performed. During the substrate processing process, because the blocking ring physically separates the gap between the substrate support device and the control ring and the lower space, a gas flowing into a reaction space may not flow into the lower space.

After the substrate processing process is completed, operation S1606 of lowering the blocking ring may be performed. The blocking ring may be supported by the transfer arm and may be lowered. When the blocking ring is lowered and no longer contacts the substrate support device and the control ring, the reaction space and the lower space may communicate with each other through the gap. In a further embodiment, when the substrate processing apparatus further includes a blocking ring support (e.g., 110 in FIG. 13) disposed in the lower space, operation S1606 of lowering the blocking ring may further include seating the blocking ring on the blocking ring support. That is, the transfer arm may lower the blocking ring to be seated on the blocking ring support.

Thereafter, operation S1607 of lowering the substrate support device may be performed. The substrate support device may be lowered by a driving unit (e.g., a driving motor).

Finally, operation S1608 of unloading the substrate by the substrate transfer mechanism may be performed.

According to a substrate processing apparatus and a substrate processing method according to embodiments of the inventive concept, a process gas may be prevented from penetrating into a space (e.g., a space under a reactor) other than a reaction space due to fluctuations in pressure or gas flow rate in the reaction space during plasma processing. Accordingly, the process gas penetrating into the space other than the reaction space may be physically prevented from generating parasitic plasma due to a potential difference formed between a gas supply unit and a lower surface of the reactor (or a chamber bottom). In addition, by blocking the gas supply unit and the lower surface of the reactor (or the chamber bottom) from facing directly through a gap between a substrate support device and a control ring, the formation of the potential difference between the gas supply unit and the lower surface of the reactor may be blocked, and the generation of parasitic plasma in the lower space of the reactor may be prevented.

The above disclosure provides a number of example embodiments and a number of representative advantages of a substrate processing apparatus capable of suppressing the generation of parasitic plasma. For the sake of brevity, only a limited number of combinations of related features have been described. It should be understood, however, that features of any example may be combined with features of any other example. Moreover, it should be understood that these advantages are non-limiting and that no particular advantage is specified nor required in any particular example embodiment.

It is to be understood that the shape of each portion of the accompanying drawings is illustrative for a clear understanding of the disclosure. It should be noted that the portions may be modified into various shapes other than the shapes shown.

The disclosure described above is not limited to the above-described embodiment and the accompanying drawings, and it will be apparent to those of ordinary skill in the art to which the disclosure pertains that various substitutions, modifications, and changes are possible within the scope of the disclosure without departing from the technical spirit of the disclosure.

According to an embodiment, parasitic plasma in a space other than a reaction space may be minimized from occurring.

According to an embodiment, a process gas in the reaction space it may be physically prevented from penetrating into a space other than the reaction space due to a change in gas flow rate or a change in process pressure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate processing apparatus including one or more reactors, wherein each reactor comprises:
an upper body;
a substrate support device;
a control ring surrounding the substrate support device and seated on a step formed in the upper body, wherein there is a gap between the control ring and the substrate support device; and
a blocking ring formed to surround the substrate support device below the gap,
wherein the upper body and the substrate support device form a reaction space,
a lower area of the substrate support device forms a lower space,
the reaction space and the lower space communicate with each other through the gap, and
an inner diameter of the blocking ring is less than or equal to an outer diameter of the substrate support device, and an outer diameter of the blocking ring is greater than or equal to an inner diameter of the control ring.

2. The substrate processing apparatus of claim 1, wherein an upper surface of the blocking ring is in contact with a lower surface of the substrate support device and a lower surface of the control ring to prevent communication between the reaction space and the lower space through the gap.

3. The substrate processing apparatus of claim 2, wherein
a protrusion surrounding an outer circumferential surface of the blocking ring is formed on the upper surface of the blocking ring,
an inner diameter of the protrusion is greater than or equal to the outer diameter of the substrate support device,
a height of the protrusion is equal to a vertical distance between the lower surface of the substrate support device and the lower surface of the control ring,
the upper surface of the blocking ring and the protrusion form a step having an upper surface, a lower surface, and a side surface connecting the upper surface to the lower surface, and
the upper surface of the step contacts the lower surface of the control ring, and the lower surface of the step contacts the lower surface of the substrate support device.

4. The substrate processing apparatus of claim 3, wherein the side surface of the step has a structure inclined toward the lower surface of the step.

5. The substrate processing apparatus of claim 3, wherein
the inner diameter of the protrusion is the same as the outer diameter of the substrate support device, and
an interface between the side surface and the lower surface of the step contacts an interface between a side surface and the lower surface of the substrate support device.

6. The substrate processing apparatus of claim 5, wherein a width of the protrusion is greater than or equal to a width of the gap.

7. The substrate processing apparatus of claim 1, wherein
the blocking ring includes one or more extensions extending from an inner circumferential surface of the blocking ring toward the center of the blocking ring, and
the one or more extensions include a through hole through which a substrate support pin passes.

8. The substrate processing apparatus of claim 7, wherein
the substrate support device includes a pin hole through which the substrate support pin passes,
wherein a bushing having a hollow through which the substrate support pin may pass is inserted into the pin hole of the substrate support device, and
the length of the bushing is greater than a thickness of the substrate support device.

9. The substrate processing apparatus of claim 8, wherein
the bushing passes through the through hole of the extension,
a thread is formed on a lower portion of the bushing,
the thread is fastened by a nut, and
the one or more extensions are between the substrate support device and the thread.

10. The substrate processing apparatus of claim 9, wherein the one or more extensions include at least one elastic body on at least one of an upper surface of the extension and a lower surface of the extension.

11. The substrate processing apparatus of claim 3, wherein the blocking ring includes one or more elastic bodies on at least one of the upper surface, the lower surface, and the side surface of the step.

12. The substrate processing apparatus of claim 1, further comprising:
a blocking ring support arranged in the lower space; and
a transfer arm configured to transfer the blocking ring.

13. The substrate processing apparatus of claim 12, wherein the transfer arm is configured to
raise the blocking ring so that the upper surface of the blocking ring contacts the lower surface of the substrate support device and the lower surface of the control ring at the start of the substrate processing process, and
lower the blocking ring to seat the blocking ring on the blocking ring support after completing the substrate processing process.

14. The substrate processing apparatus of claim 13, wherein the block ring support includes a step having an inclined structure.

15. A substrate processing apparatus including one or more reactors, wherein each reactor comprises:
an upper body;
a substrate support device; and
a control ring apart from the substrate support device, surrounding the substrate support device, and seated on a step formed in the upper body,
wherein a protrusion is formed in a lower portion of the substrate support device along an outer circumferential surface of the substrate support device, and
the protrusion extends from a side surface of the substrate support device to a lower portion of the control ring.

16. The substrate processing apparatus of claim 15, wherein the protrusion contacts the lower surface of the control ring.

17. A substrate processing method using the substrate processing apparatus of claim 1, the substrate processing method comprising:
lowering the substrate support device;
loading a substrate into the substrate support device;
raising the substrate support device;
raising the blocking ring so that an upper surface of the blocking ring contacts a lower surface of the substrate support device and a lower surface of the control ring;
performing a substrate processing process;
lowering the blocking ring;
lowering the substrate support device; and
unloading the substrate.

18. The substrate processing method of claim 17, wherein,
when the blocking ring does not contact the lower surfaces of the substrate support device and the control ring, the reaction space and the lower space communicate with each other through the gap, and,
when the blocking ring contacts the lower surfaces of the substrate support device and the control ring, the reaction space and the lower space do not communicate with each other.

19. The substrate processing method of claim 17, wherein, during the substrate processing process, a gas introduced into the reaction space does not flow into the lower space by the blocking ring.

20. The substrate processing method of claim 17, wherein the substrate processing apparatus further comprises:
a blocking ring support arranged in the lower space; and
a transfer arm configured to transfer the blocking ring,
wherein the lowering of the blocking ring includes seating the blocking ring on the blocking ring support by the transfer arm.
